(19) United States
(12) Patent Application Publication
(10) Pub. No.: US 2005/0185479 A1
(43) Pub. Date: Aug. 25, 2005

(54) Method and device for saving and setting a circuit state of a microelectronic circuit

(75) Inventor: Jorg Berthold, Munich (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(73) Assignee: Infineon Technologies AG

(21) Appl. No.: 11/043,836

(22) Filed: Jan. 26, 2005

(30) Foreign Application Priority Data
Jan. 30, 2004 (DE) 10 2004 004808.8

(51) Int. Cl. G11C 7/00

(52) U.S. Cl. 365/189.12

(57) ABSTRACT

Methods and devices for saving and/or setting a circuit state of a microelectronic circuit that includes at least one scan chain for testing the circuit are disclosed. In this connection, the at least one scan chain is used to save and/or set the circuit state, as a result of which an expansion of the circuit is unnecessary.

### CROSS-REFERENCE TO RELATED APPLICATIONS

This Utility Patent Application claims priority to German Patent Application No. DE 10 2004 004808.8, filed on Jan. 30, 2004, which is incorporated herein by reference.

### BACKGROUND

The present invention relates to methods for saving and setting a circuit state or operating state of a microelectronic circuit that comprises at least one scan chain for testing the circuit and also appropriate devices.

In the case of a circuit in CMOS technology, in particular, disconnection of at least one part of the circuit is an effective measure for reducing the power consumption of the circuit if certain circuit parts are not needed since leakage currents of transistors can thereby be avoided. One disconnection problem is restoring or setting the operating state of the circuit. In addition to reapplying supply voltages, storage elements (registers) of the disconnected circuit have to be initialized during switching-on. In this connection, it is not sufficient in many cases to initialize all the registers of the circuit with zero since in these cases the registers have to be written with the values that were stored before the disconnection.

FIG. 1 illustrates a block circuit diagram of parts of a microelectronic system according to the prior art, wherein the circuit section 2 is to be disconnected. Prior to the disconnection, contents of registers R1, R2, R3 of the circuit section 2 that are needed to restore the operating state of the circuit section 2 are normally transferred via a bus 6 to a register file 7. In the example illustrated in FIG. 1, the contents of the registers R1 and R3 are saved in the registers R4 and R5 of the register file 7. This method according to the prior art is problematical. On one hand, a special wiring is needed that makes it possible for the contents of the registers R1 and R3 of the circuit section 2 to be placed on the bus 6. On the other hand, during the saving of the contents of the register, the bus 6 is “busy” and cannot be used for other operations.

FIG. 2 illustrates the circuit section 2 in detail, in which connection the registers R1 or R2 or R3 from FIG. 1 may be represented by eight 1-bit registers A1-A8 or B1-B8 or C1-C8, respectively. For reasons of testability all the registers A1-8, B1-8, C1-8 are normally disposed, according to the prior art, in so-called scan chains. With the aid of one or more scan chains, all the registers are combined to form one or more shift registers, as a result of which all the registers can be written and read for test purposes. This transforms the problem of testing sequential circuits into the essentially simpler problem of testing combinatory circuits. In the example illustrated in FIG. 2, all the registers are combined by means of a scan chain 14. The scan chain 14 is activated under these circumstances by means of a test control system 4.

In the example illustrated in FIG. 2, the 1-bit registers A1-C8 are irregularly distributed over the circuit section 2, which is frequently the case, in particular, for semi-custom circuits and finite state machines. For test purposes, all the registers A1-C8 are a component of a scan chain 14 whose input is connected with an input terminal 12 of the circuit section 2 and whose output is connected with an output terminal 13 of the circuit section, the scan chain 14 thereby being connected to a test control system 4. The actual input/outputs of the circuit section 2 are denoted in FIG. 2 by io1-8. In this type of circuit, it would require an appreciable wiring complexity in order to access all the 1-bit registers A1-C8 directly via a parallel bus 6, as is usual in the prior art, in order to save and set the operating state.

A further possibility for disconnecting at least one section of the circuit section 2 without having to save the operating state prior to the disconnection and to set it again after switching on again consists, according to the prior art, in distributing an additional supply voltage within the circuit section 2 and connecting all the registers A1-C8 thereto. In this case there is the disadvantage that, on the one hand, the entire circuit section 2 cannot be disconnected and, on the other hand, an additional wiring is needed for the additional supply voltage.

For these and other reasons, there is a need for the present invention.

### SUMMARY

One embodiment of the present invention provides a method for saving a circuit state of a microelectronic circuit including at least one scan chain for testing the circuit. In this connection, the method uses the at least one scan chain to save the circuit state in such a way that contents of the at least one scan chain are shifted into at least one memory.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a block circuit diagram of sections of a microelectronic system according to the prior art in which a circuit section is occasionally disconnected.

FIG. 2 illustrates the circuit section from FIG. 1 in greater detail.

FIG. 3 illustrates a device according to one embodiment of the invention together with a circuit in which all the registers are combined in a scan chain.

FIG. 4 illustrates a device according to one embodiment of the invention together with a circuit that is similar to the circuit from FIG. 3.

FIG. 5 illustrates a block circuit diagram of a device according to one embodiment of the invention, including a memory, a circuit and a status register.

FIG. 6 illustrates a timing diagram for saving and restoring a circuit state.

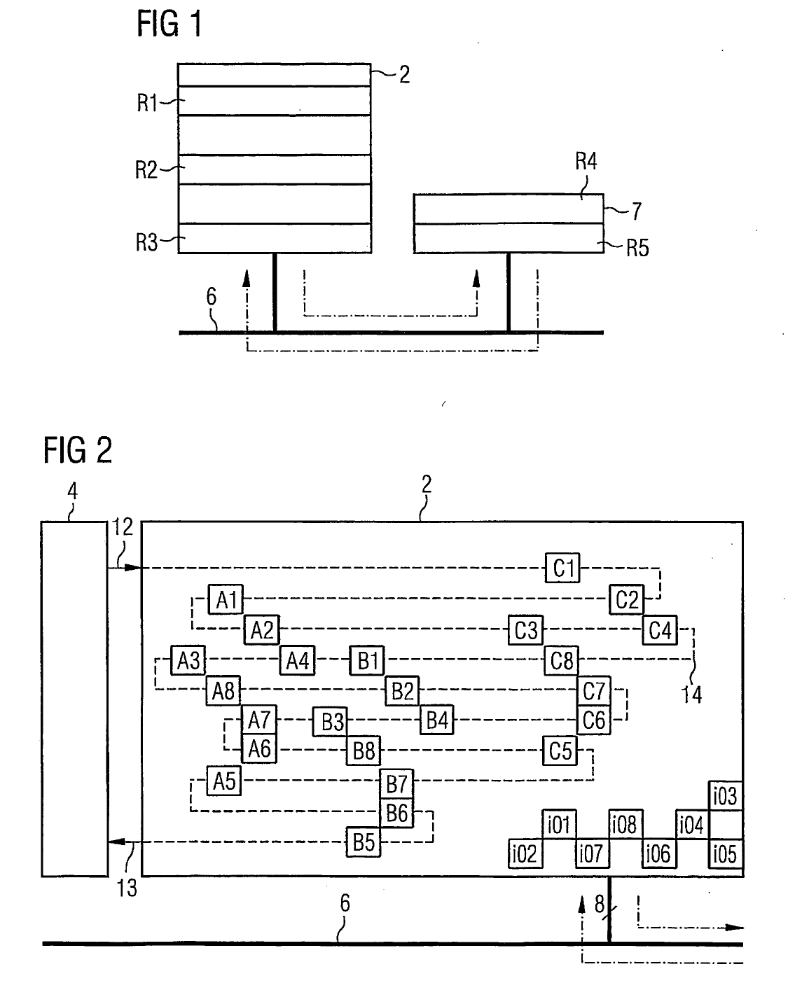

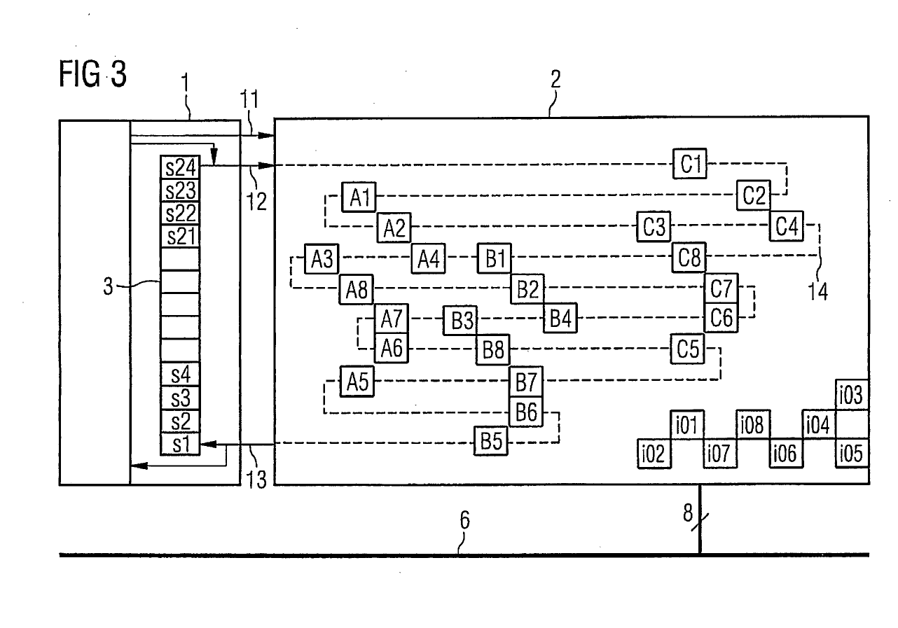

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One embodiment of the invention provides a method and associated device for saving or setting an operating state of a microelectronic circuit. By using a scan chain to save the circuit state, which scan chain is otherwise used only for testing the circuit and is superfluous or troublesome during a non-test phase of the circuit according to the prior art, the circuit state of the circuit can be saved without the circuit having to be expanded in any way, as is necessary to save the circuit state according to the prior art.

In this connection, in one embodiment of the method, the contents of the at least one scan chain can be shifted into the at least one memory as soon as it is detected that a control signal has a predetermined value. In addition, a confirmation signal can be set to a predetermined value as soon as shifting of the contents of the at least one scan chain into the at least one memory is started.

The method for saving the circuit state can be started with the aid of the control signal, the confirmation signal indicating that the circuit state is currently being saved.

Furthermore, in one embodiment a clock signal will be fed to the at least one memory and the at least one scan chain until the contents of the at least one scan chain have been shifted into the at least one memory. In this connection, the circuit is additionally brought with the aid of a test initiating signal of the circuit to a state in which it is possible to shift out the contents of the at least one scan chain by means of a shift operation of the scan chain.

The method thereby performs all the necessary steps to shift a circuit state stored in one or more scan chains out of said one or said more scan chains into one or more memories.

One embodiment of the present invention also provides a method for setting a circuit state of a microelectronic circuit that comprises at least one scan chain for testing the circuit. In this connection, the at least one scan chain for setting the circuit state is used in such a way that contents of at least one memory are shifted into the at least one scan chain.

Since one or more scan chains are used to set the circuit state, which scan chains are already a component of the circuit, but are used according to the prior art exclusively for testing the circuit, the circuit does not need, according to one embodiment of the invention, to be expanded to set the circuit state, as is necessary according to the prior art.

According to one embodiment of the invention, the contents of the at least one memory are shifted into the at least one scan chain as soon as it is detected that a control signal has a predetermined value. Additionally, a confirmation signal can be set to a predetermined value as soon as the contents of the at least one memory have been shifted into the at least one scan chain.

As a result, the method for setting the circuit state can be started with the aid of the control signal, the confirmation signal indicating that the circuit state is being set.

In one embodiment, the contents of the at least one memory are shifted into the at least one scan chain by a clock signal being fed to the at least one memory and the at least one scan chain until the contents of the at least one memory have been shifted into the at least one scan chain. During said shift operation, the circuit is brought, with the aid of a test initiation signal, to a state in which it is possible to shift in the contents of the at least one scan chain by means of a shift operation of the scan chain.

One embodiment of the method consequently controls all the steps necessary to set, with the aid of the at least one scan chain, any desired circuit state that has previously been written into the at least one memory.

The method for setting the circuit state may also be used, for example, to reconfigure the circuit or to change its configuration.

With one embodiment of the present invention, a method is also provided for saving and restoring a circuit state of a microelectronic circuit that comprises at least one scan chain for testing the circuit. In this connection, said method is based on the previously disclosed method for saving a circuit state and on the likewise previously disclosed method for setting a circuit state.

To save and restore the circuit state of the circuit, said method uses one or more scan chains that, according to the prior art, are used exclusively for testing the circuit. Thus, one embodiment of the method does not require an expansion (for example additional wiring or additional components) of the circuit. With the aid of said method, it is possible to save a circuit state of a circuit or of a circuit section that is to be disconnected to save energy prior to disconnecting the circuit and to set the saved circuit state again after the supply voltage of the circuit is switched on again. As a result, after the supply voltage has been switched on again, the circuit is capable of continuing, without problems, an operation that it had begun prior to the disconnection.

One embodiment of the present invention likewise provides a device for saving a circuit state of a microelectronic circuit that comprises at least one scan chain for testing the circuit. In this connection, one embodiment of the device is designed in such a way that it activates the at least one scan chain and at least one memory to save the circuit state in such a way that contents of the at least one scan chain are shifted into the at least one memory.

The device can be designed in such a way that it disconnects a supply voltage for the circuit as soon as it has shifted the contents of the at least one scan chain into the at least one memory by means of the at least one scan chain and by means of the at least one memory.

Since one embodiment of the device itself disconnects the supply voltage of the circuit after it has saved the circuit state of the circuit, a master control device that would like to disconnect the circuit only has to activate the device accordingly. Since the supply voltage of the circuit can, in addition, only be disconnected after the circuit state of the circuit has been shifted into the at least one memory, it is advantageous in one embodiment that the device disconnects the supply voltage since the device best has knowledge about when the circuit state of the circuit has been completely shifted into the at least one memory.

According to one embodiment of the invention, the at least one memory may be at least one shift register.

Since the at least one scan chain is one or more shift registers, it is advantageous in one embodiment, for synchronization reasons, if the at least one memory into which the contents of the at least one scan chain are shifted is/are also one or more shift registers.

According to one embodiment of the invention, the device, together with the circuit, may belong to a master microelectronic circuit, in which case the circuit may belong to an area of the master microelectronic circuit in which the supply voltage can be disconnected. In one case, the device then belongs to an area of the master microelectronic circuit in which the supply voltage cannot be disconnected at least during a time at which the supply voltage of the circuit is disconnected. In addition, the device may then comprise at least one memory.

Since one embodiment of the device together with the at least one memory is a component of the master microelectronic circuit to which the disconnectable circuit also belongs, the circuit can be disconnected within the master microelectronic circuit without the circuit state of the circuit being lost since the master microelectronic circuit is, owing to the device according to one embodiment of the invention, capable of saving the circuit state of the circuit autarkically in the at least one memory that belongs to the device and, consequently, to the master microelectronic circuit.

Furthermore, one embodiment of the present invention comprises a device for setting a circuit state of a microelectronic circuit that comprises at least one scan chain for testing the circuit. In this connection, the device is designed in such a way that it activates the at least one scan chain and at least one memory to set the circuit state in such a way that contents of the at least one memory are shifted into the at least one scan chain.

According to one embodiment of the invention, the device may be designed in such a way that it switches on a supply voltage for the circuit before it shifts the contents of the at least one scan chain by means of the at least one scan chain and by means of the at least one memory.

Since one embodiment of the device itself switches on the supply voltage of the circuit before it sets the circuit state of the circuit, a master control device that would like to put the disconnected circuit into operation again advantageously only has to activate the device accordingly. Since, in addition, the shifting into the at least one scan chain can only be started if the supply voltage is applied everywhere in the circuit, it is advantageous that one embodiment of the device itself switches on the supply voltage of the circuit since the device is thereby very well capable of estimating when the supply voltage is applied for all the components of the circuit.

One embodiment of the device together with the circuit belongs to a master microelectronic circuit, the circuit belonging to an area of the master microelectronic circuit, in which area the supply voltage can be disconnected. On the other hand, one embodiment of the device should belong to an area of the master microelectronic circuit, in which area the supply voltage can at least not be disconnected if the supply voltage of the circuit is disconnected. Additionally, the at least one memory may belong to the device.

This ensures that the master microelectronic circuit can switch on the supply voltage of the circuit autarkically by means of the device and can then bring the circuit to a circuit state again by means of the device, which circuit state is preselected by loading the at least one memory that is likewise a component of the device and, consequently, of the master microelectronic circuit.

Furthermore, one embodiment of the present invention provides a device for saving and restoring a circuit state of a microelectronic circuit that comprises at least one scan chain for testing the circuit. In this connection, the device is designed both to save a circuit state in accordance with the previously described device and to set a circuit state in accordance with the likewise previously described device.

In this connection, one embodiment of the device together with the circuit may belong to a master microelectronic circuit, the circuit belonging to an area of the master microelectronic circuit, in which area the supply voltage can be disconnected. On the other hand, one embodiment of the device should belong to an area of the master microelectronic circuit, in which area the supply voltage can at least not be disconnected if the supply voltage of the circuit is disconnected.

Such a master microelectronic circuit is autarkically capable of rescuing the circuit state of the circuit at almost any desired instant in time by means of the device according to the invention and then switching off the supply voltage of the circuit by means of the device in order thereby to save energy. As soon as the master electronic circuit detects that the operation of the circuit has to be continued, the supply voltage of the circuit is switched on again with the aid of the device and the previously rescued circuit state is then set again by means of the device.

One embodiment of the device may, however, also be used to reconfigure or to change the configuration of the circuit. Disconnecting or switching the supply voltage on then lapses. The circuit state set in the case of reconfiguration may be a circuit state that has been rescued beforehand by means of the device. It may, however, also be a circuit state generated elsewhere (for example, with the aid of circuit design tools) that the circuit has never assumed before.

One embodiment of the present invention is suitable in the case of CMOS circuits for disconnecting a certain circuit section temporarily for energy saving measures in order to switch it on again later if it is needed again. Of course, the invention is not restricted to CMOS technologies but can be used in a circuit of any technology in which all the registers that are needed to set a circuit state of the circuit are incorporated in one or more scan chains.

FIG. 3 illustrates diagrammatically a device 1 that comprises a shift register 3, together with a circuit 2, the device 1 as well as the circuit 2 belonging to a master microelectronic circuit. In this connection, all the registers A1-C8 in the circuit 2 are incorporated in a scan chain 14. Additionally, the circuit 2 has inputs/outputs io1-8 that can be set or read out via a bus 6. While the circuit 2 belongs to an area of the master microelectronic circuit, in which area the associated supply voltage can be disconnected, the device 1 belongs to an area of the master microelectronic circuit, in which area the associated supply voltage is always applied.

Steps that are taken before the supply voltage of the circuit 2 is disconnected are now described below. First, the device 1 sets a test initiation signal 11 of the circuit 2 to a predetermined value. As a result, the circuit 2 is brought to a state such that the scan chain 14 can be operated like a shift register. Additionally, the device 1 ensures that a clock signal (not shown) of the circuit 2 remains active (number of clock cycles necessary for saving=number of registers A1-C8 in the scan chain 14=24) until all the registers A1-C8 incorporated in the scan chain 14 have shifted their values into the shift register 3 via a scan-chain output terminal 13 of the circuit 2, which terminal is connected to an input of the shift register 3. The clock signal then deactivates the device 1, resets the test initiation signal 11 and disconnects the supply voltage of the circuit 2.

It may be noted that the device 1 is capable of operation only if the shift register 3 assigned to it comprises at least as many 1-bit memory locations as there are registers A1-C8 incorporated in the scan chain 14.

The steps that switch the supply voltage of the circuit 2 on again and to set a previously saved circuit state or another circuit state defined by the content of the shift register 3 is now described. First the device 1 switches on the supply voltage of the circuit 2. Just as in the case of saving the circuit state, the device 1 then brings the circuit 2 by means of the test initiation signal 11 to a state such that the scan chain 14 can be operated like a shift register. Additionally, the device 1 ensures that the clock signal of the circuit 2 is activated so that all 24 registers A1-C8 incorporated in the scan chain 14 can be set according to the content of 24 1-bit register cells s1-s24 of the shift register 3 via a scan-chain input terminal 13 of the circuit 2 that is connected to an output of the shift register 3. After 24 clock cycles, the device 1 resets the test initiation signal 11, as a result of which the circuit 2 is again capable of normal operation.

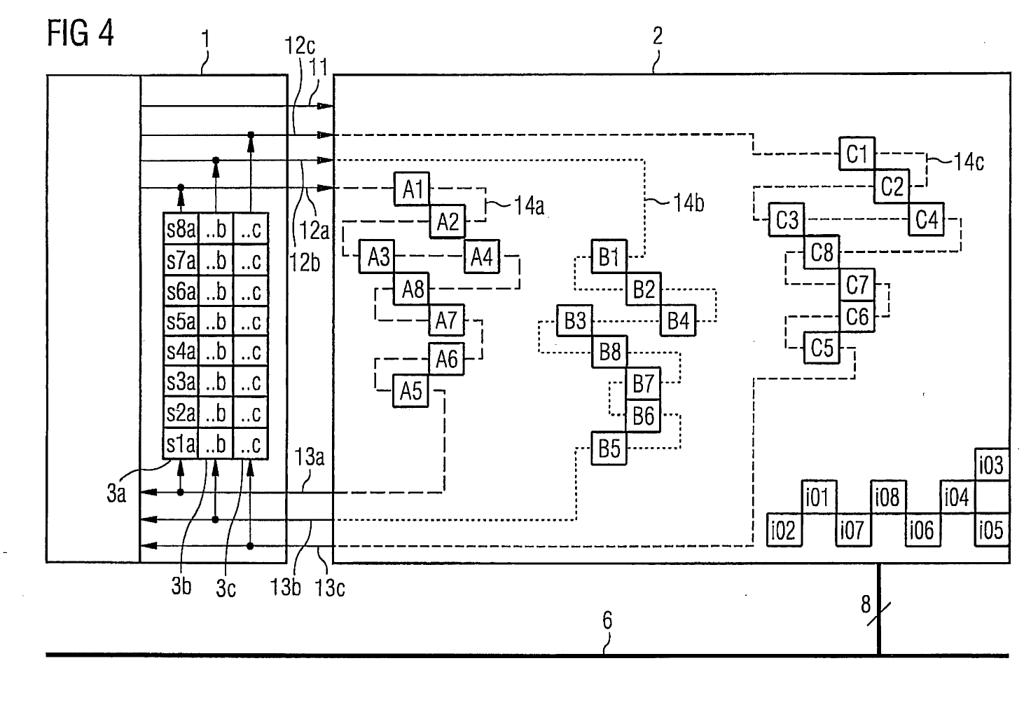

FIG. 4 illustrates a device 1 for saving and setting a circuit state together with a circuit 2. In contrast to the circuit 2 of FIG. 3, the registers A1-C8 of the circuit 2 are incorporated in three scan chains 14a-c, the registers A1-8 belonging to a scan chain 14a, the registers B1-8 belonging to a scan chain 14b and the registers C1-8 belonging to a scan chain 14c. For this reason, the device 1 also comprises three 8-bit-stage shift registers 3a-c instead of one 24-bit-stage shift register 3, an input of the first shift register 3a being connected to an output of the first scan chain 14a and an output of the first shift register 3a being connected to an input of the first scan chain 14a. In exactly the same way, an input of the second shift register 3b or of the third shift register 3c is connected to an output of the second scan chain 14b or third scan chain 14c, respectively, and an output of the second shift register 3b or third shift register 3c is connected to an input of the second scan chain 14b or 14c, respectively. The first shift register 3a comprises, in this connection, the eight 1-bit register cells s1a-s8a, the second shift register 3b comprises the eight 1-bit register cells s1b-s8b and the third shift register 3c comprises the eight 1-bit register cells s1c-s8c.

The mode of operation during saving or setting a circuit state of the device 1 essentially corresponds to the mode of operation of the device 1 from FIG. 3. The sole difference is that the device 1 of FIG. 4 needs only eight clock cycles in order to save or set the registers A1-C8 disposed in the three scan chains 14a-14c.

The circuit example illustrated in FIG. 4 illustrates that in one embodiment it is advantageous if the memory assigned to the device 1 has as many 1-bit-wide shift registers 3a-c as the circuit 2 has scan chains 14a-c. In addition, each shift register has at least as many memory cells as there are registers contained in the scan chain assigned to it. However, a memory that has one 1-bit-wide shift register comprising 24 memory cells is, for example, also conceivable for the device 1 of FIG. 4. In that case, the device 1 needs, however, an aid in order, on the one hand, to serialize the bits arriving in parallel from the three scan chains 14a-c and, on the other hand, to parallelize the bits arriving serially from the shift register for the three scan chains 14a-c.

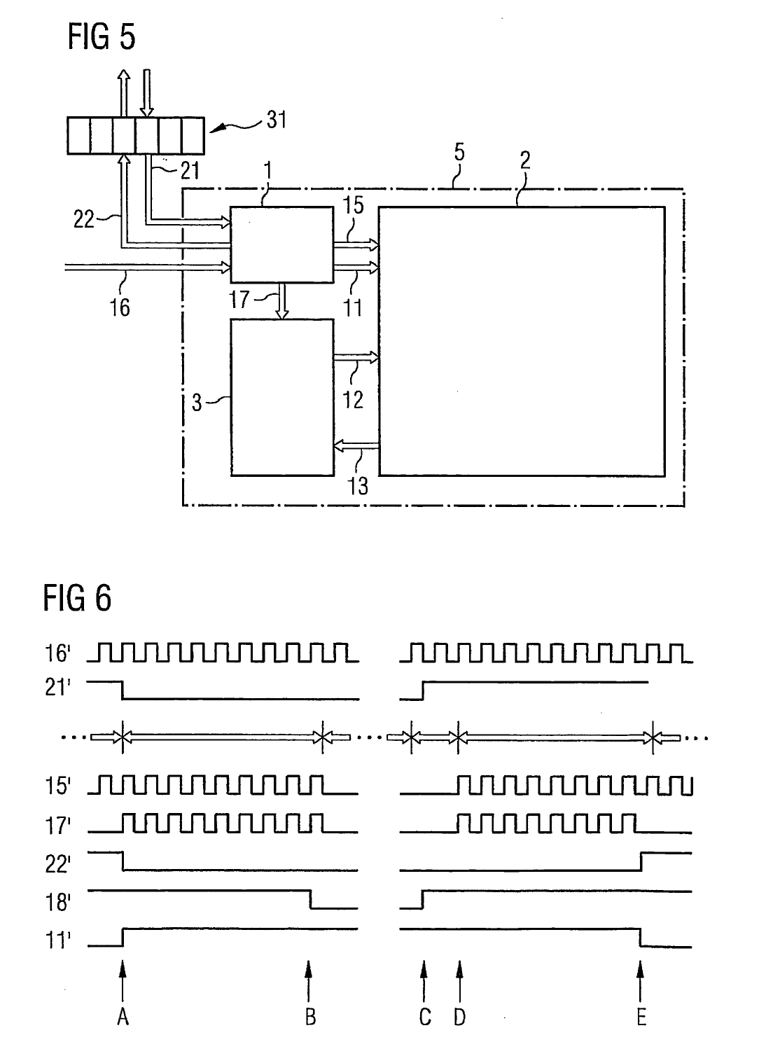

FIG. 5 illustrates a block circuit diagram that comprises a device 1, a memory 3, a circuit 2 and a status register 31. In this connection, let it be assumed that the circuit 2 corresponds to the circuit 2 of FIG. 4 and that the memory 3 comprising three shift registers 3a-c is constructed as illustrated in FIG. 4. If the bit corresponding to a control signal 21 is set to 0 in the status register 31, the device 1 sets, by means of the confirmation signal 22, a bit linked to the confirmation signal 22 in the status register 31 to the value 0. Additionally, the device 1 starts to save the circuit state of the circuit 2 with the aid of the shift registers 3a-3c and then disconnects the supply voltage of the circuit 2 as is illustrated more comprehensively with the aid of FIG. 6. If the bit corresponding to the control signal 21 is set to the value 1 again, the device 1 switches on the supply voltage of the circuit 2 again and begins to set the previously saved circuit state of the circuit 2 again, the corresponding bit in the status register 31 finally being set to the value 1 by means of the confirmation signal 22, which signals that the circuit 2 is ready to operate.

FIG. 6 illustrates a timing diagram for saving and setting the circuit state. In this diagram, A denotes the beginning of the saving of the circuit state, B denotes the beginning of the disconnection of the supply voltage of the circuit 2, C denotes the beginning of the switching on again of the supply voltage of the circuit 2, D denotes the beginning of the setting of the circuit state and E denotes the beginning of normal operation of the circuit 2. In this connection, the timing diagram of FIG. 6 represents a time variation of the most important signals, a time variation of a signal X being denoted by the reference symbol X′, for example, the time variation of the control signal 21 is denoted by the reference symbol 21′.

If the bit corresponding to the control signal 21 in the status register 31 is set to the value 0, the device 1, on the one hand, sets the confirmation signal 22 to the value 0 and, on the other hand, sets the test initiation signal 11 to the value 1, which brings the circuit 2 to a state in which the scan chains 14a-c of the circuit 2 can be operated like shift registers. Additionally, the device 1 conveys a clock set to it by means of a clock signal 16 to the memory 3 by means of a clock signal 17, it interrupting this conveyance and also a conveyance via a clock signal 15 to the circuit 2 after a number of clock cycles that is sufficient in order to shift the content of the registers A1-C8 of the circuit 2 to the shift registers 3a-c by means of the scan chains 14a-c. The device 1 then disconnects the supply voltage of the circuit 2, the time variation of the disconnection being shown at reference symbol 18′. Said disconnection may be brought about, for example, by disabling a large FET transistor (not shown).

In order to resume the operation of the circuit 2, the bit corresponding to the control signal 31 in the status register 31 is set to the value 1. The device 1 then switches on the supply voltage of the circuit 2 again. After a time interval that is sufficient for all the components of the circuit 2 to be ready for operation, the device 1 conveys the clock fed to it by means of the clock signal 16 to the circuit 2 by means of the clock signal 15 and to the shift registers 3a-c by means of the clock signal 17. Since the test initiation signal 11 is still at the value 1, the circuit continues to be in a state in which the scan chains 14a-c function as shift registers. As a result, the content of the shift registers 3a-c is shifted into the scan chains 14a-c by conveying the clock to the shift registers 3a-c and the circuit 2, which switches on the previously saved circuit state again. After a number of clock cycles that corresponds to the longest scan chain (number of registers in the scan chain) of the circuit 2, the device 1 interrupts the conveyance of the clock to the shift register 3 by means of the clock signal 17. Simultaneously, the device 1 resets the test initiation signal to the value 0, which brings the circuit 2 to the normal operating state in which the scan chains no longer operate as shift registers. In addition, simultaneously therewith, the corresponding bit of the status register 31 is set to the value 1 by means of the confirmation signal 22, which indicates that the circuit 2 is operating normally again.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A method for saving a circuit state of a microelectronic circuit, comprising:
testing the circuit having at least one scan chain;
saving the circuit state with the at least one scan chain; and
shifting contents of the at least one scan chain into at least one memory.

2. The method of claim 1, further comprising feeding a clock signal to the at least one memory and the at least one scan chain until the contents of the at least one scan chain have been shifted into the at least one memory.

3. The method of claim 1, further comprising bringing the circuit by setting a test initiation signal to a certain value, to a state in which it is possible to shift out the contents of the at least one scan chain by means of a shift operation of the scan chain if the contents of the at least one scan chain are shifted into the at least one memory.

4. The method of claim 1, further comprising disconnecting the supply voltage for the circuit as soon as the contents of the at least one scan chain have been shifted into the at least one memory.

5. A method for setting a circuit state of a microelectronic circuit, comprising:
testing the circuit with at least one scan chain; and
using the at least one scan chain to set the circuit state in such a way that contents of at least one memory are shifted into the at least one scan chain.

6. The method of claim 5, further comprising feeding a clock signal to the at least one memory and the at least one scan chain until the contents of the at least one memory have been shifted into the at least one scan chain.

7. The method of claim 5, further comprising bringing the circuit by setting a test initiation signal to a certain value, to a state in which it is possible to shift in the contents of the at least one scan chain by means of a shift operation of the scan chain if the contents of the at least one memory are shifted into the at least one scan chain.

8. The method of claim 5, further comprising switching the supply voltage on for the circuit before the contents of the at least one memory are shifted into the at least one scan chain.

9. A circuit apparatus comprising:
a microelectronic circuit having a circuit state and comprising at least one scan chain for testing the microelectronic circuit; and
means for saving the circuit state, wherein the means for saving the circuit state activates the at least one scan chain and at least one memory to save the circuit state in such a way that the contents of the at least one scan chain are shifted into the at least one memory.

10. The apparatus of claim 9, further comprising a clock signal supplied to the at least one scan chain and the at least one memory until the contents of the at least one scan chain have been shifted into the at least one memory.

11. The apparatus of claim 9, further comprising a test initiation signal of the microelectronic circuit that is set to a predetermined value in order to shift the contents of the at least one scan chain into the at least one memory, and wherein the microelectronic circuit is brought, if the test initiation signal is at a predetermined value, to a state in which it is possible to shift out the contents of the at least one scan chain by means of a shift operation of the scan chain.

12. The apparatus of claim 9, wherein a supply voltage for the circuit is disconnected as soon as the contents of the at least one scan chain have shifted into the at least one memory by means of the at least one scan chain and by means of the at least one memory.

13. The apparatus of claim 9, wherein the at least one memory is at least one shift register.

14. The apparatus of claim 9, wherein the means for saving the circuit state comprises the at least one memory.

15. The apparatus of claim 9, wherein the means for saving the circuit state and the microelectronic circuit belong to a master microelectronic circuit, wherein the microelectronic circuit belongs to an area of the master electronic circuit where the supply voltage can be disconnected, and wherein the device means for saving the circuit state belongs to an area of the master microelectronic circuit where the supply voltage cannot be disconnected.

16. A circuit apparatus comprising:
a microelectronic circuit having a circuit state and comprising at least one scan chain for testing the microelectronic circuit; and
means for activating the at least one scan chain and at least one memory in order to set the circuit state in such a way that contents of the at least one memory are shifted into the at least one scan chain.

17. The apparatus of claim 16, further comprising a clock signal fed to the at least one scan chain and to the at least one memory until the contents of the at least one memory have been shifted into the at least one scan chain.

18. The apparatus of claim 16, further comprising a test initiation signal of the microelectronic circuit that is set to a predetermined value in order to shift the contents of the at least one memory into the at least one scan chain, and wherein, if the test initiation signal is at the predetermined value, the microelectronic circuit is brought to a state in which it is possible to shift in the contents of the at least one scan chain by means of a shift operation of the scan chain.

19. The apparatus of claim 16, wherein a supply voltage for the microelectronic circuit is switched on before the contents of the at least one memory are shifted into the at least one scan chain by means of the at least one scan chain and by means of the at least one memory.

20. The apparatus of claim 16, wherein the at least one memory is at least one shift register.

21. The apparatus of claim 16, wherein the means for activating comprises the at least one memory.

22. The apparatus of claim 16, wherein the means for activating and the microelectronic circuit belong to a master microelectronic circuit, wherein the microelectronic circuit belongs to an area of the master microelectronic circuit where the supply voltage can be disconnected, and wherein the means for activating belongs to an area of the master microelectronic circuit where the supply voltage cannot be disconnected.
